(19) United States
(12) Patent Application Publication
(10) Pub. No.: US 2010/0293424 A1
(43) Pub. Date: Nov. 18, 2010

(54) SEMICONDUCTOR INTEGRATED CIRCUIT, INFORMATION PROCESSING APPARATUS AND METHOD, AND PROGRAM

(76) Inventors: Masanobu Katagi, Kanagawa (JP); Asami Yoshida, Kanagawa (JP); Hirotake Yamamoto, Hokkaido (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/776,925

(22) Filed: May 10, 2010

(30) Foreign Application Priority Data
May 18, 2009 (JP) P2009-120411

(51) Int. Cl. G01R 31/3177; G06F 11/25

(52) U.S. Cl. 714/728; 714/E11.155

(57) ABSTRACT

A semiconductor integrated circuit includes: a plurality of flip-flops connected to a scan chain set as a test path of an integrated circuit; and a data-collection section inputting setting values of the plurality of flip-flops connected to the scan chain through the scan chain or an independent connection path, wherein the data-collection section inputs the setting values of the flip-flops at the time the power has been turned on to the plurality of flip-flops, and performs generation processing of random numbers, or random-number generation data, or fixed data on the basis of the input values.

### BACKGROUND OF THE INVENTION

1. Field of the Invention

The present invention relates to a semiconductor integrated circuit, information processing apparatus and method, and program. More particularly, the present invention relates to a semiconductor integrated circuit, information processing apparatus and method, and program which performs generation processing of data, such as random numbers or an ID, etc.

2. Description of the Related Art

In digital circuits in an electronic apparatus, a large number of flip-flops (FFs) are used for holding bit values and a transfer processing circuit. A flip-flop (FF) holds a bit value (0,1), and is capable of inputting/outputting bit values at a high speed. For example, a flip-flop is often used as an element for forming a cache memory, a register, and the other electronic circuits. In this regard, hereinafter in the present specification, a flip-flop is sometimes expressed as an FF.

A bit value of 0 or 1 can be set by a flip-flop (FF). However, it is a common knowledge that a value to be set at power-on time is often not determined to be either 0 or 1, and becomes an uncertain value.

A random number generator using uncertainty of the setting value of a flip-flop (FF) at power-on time has been disclosed in T. E. Tkacik, “A Hardware Random Number Generator”, CHES2002, LNCS vol. 2523, Springer-Verlag, 2003, pp. 450-453 (hereinafter referred to as a first non-patent document). The first non-patent document has disclosed a random number generator using a flip-flop (FF) forming a linear-feedback shift register (LFSR), and a cellular-automata shift register (CASR). In order to operate an LFSR or a CASR, initial values are originally necessary. In the random number generator disclosed in the first non-patent document, uncertain values at power-on time of an FF, which holds a state, are held so that initial values of the LFSR and the CASR are varied each time power is turned on.

Also, an SRAM memory cell is provided as an element having a similar structure as the flip-flop (FF) described in the first non-patent document. It is also a common knowledge that setting values of many SRAM memory cells at power-on time become uncertain values. In D. E. Holcomb, W. P. Burleson, and K. Fu., “Initial SRAM state as a fingerprint and source of true random numbers for RFID tags”, Conference on RFID Security 07, Jul. 11-13, 2007 (hereinafter referred to as a second non-patent document), a proposal has been made of a method of using a cell having random values for generating random numbers, and using a cell indicating a fixed value for generation of a chip-ID among the cells having uncertain values utilizing the characteristic of an SRAM at power-on time.

Generation Principle of Uncertain Values

As disclosed in the above-described first and second non-patent documents, it is a familiar fact that an FF and an SRAM memory cell have uncertain values at power-on time. In the following, a brief description will be given of a generation principle of uncertain values with reference to the drawings.

The fact that both of the elements indicate uncertain values at power-on time arises from the structures of the elements. FIG. 1 is a diagram illustrating a structure of a D flip-flop (D-FF). FIG. 1(a) illustrates an overall structure, and FIG. 1(b) illustrates a detailed structure.

FIG. 2 is a diagram illustrating a structure of a memory cell of an SRAM. FIG. 2(a) illustrates an overall structure, and FIG. 2(b) illustrates a detailed structure of one memory cell.

Both of the elements have a structure including two inverters connected with each other in order to memorize bit information 0 or 1. They are inverters 11 and 12 in FIG. 1, and inverters 21 and 22 in FIG. 2.

FIG. 3A is a partial view of a structure including inverters 31 and 32 connected with each other, which is common to a flip-flop (FF) and an SRAM cell. In the inverter connection structure shown in FIG. 3A, individual potentials of A and B can have two stable states, (H, L) or (L, H). The FF and the SRAM cell store the two stable states by individually relating to 1 and 0 of digital data as FF-setting-value data.

At normal operating time, in order to determine the FF setting values to be either one of the stable states, control is performed, such as continuous application of a voltage, etc., from the outside, and thus the FF setting values do not become uncertain values. However, at power-on time, the initial setting values are determined by manufacturing variations of the transistors, voltage variations, noise, etc., and thus at which value the initial state is stabilized is different for each element.

FIG. 3B is a diagram illustrating the element shown in FIG. 3A by a MOSFET level. In FIG. 3B, consideration is given to a process of an initial state at power-on time, that is to say, a process when a voltage of a member X in the structure shown in FIG. 3B changes from 0 to Vdd. When the member X has a voltage of 0, PMOSs 41 and 42 are both in an ON state, and thus potentials of A and B are 0.

When the power is turned on, the potentials of A and B go up. If the threshold values of the PMOSs 41 and 42 do not completely match, a PMOS having a lower threshold value becomes an OFF state. In this case, the potential of either of the PMOSs A and B that has become OFF decreases to 0, and either A or B finally becomes a stable state (Vdd, 0) or (0, Vdd). In general, the threshold values of MOS transistors do not match by manufacturing variations of transistors, voltage variations, noise, etc., and thus a stable value at power-on time is determined by physical conditions, and is different for each element, thereby becoming uncertain.

In this regard, the initial setting value is different because of the difference in characteristic for each FF and for each SRAM cell. Some element indicates a different value at each power-on time, and is distinguished from an element indicating a fixed value all the time. This is determined by the threshold values and the physical conditions of both of the PMOSs.

In this manner, individual FF values are divided into random values each time power is turned on, and fixed values. In the method of the above-described first non-patent document, only about 40 FFs at most are used. Accordingly, in a situation including a large number of FFs having fixed values, random numbers might not be sufficiently obtained. In this regard, the similar problems are pointed out in M. Dichtl, “How to predict the Output of a Hardware Random Number Generator”, CHES2003, LNCS vol. 2779, Springer-Verlag, 2003, pp. 181-188 (hereinafter referred to as a third non-patent document). As a countermeasure against this problem, it is thought that the number of FFs is increased, but this causes an increase in a package area. Thereby, it is difficult realistically.

In the configuration of the second non-patent document, SRAM memory cells are used in place of FFs, and thus it is possible to ensure abundant cells that are uncertain and vary at random. The second non-patent document has revealed that 2048-bit memory cell data was necessary for obtaining random bits of 128-bit length. Accordingly, it becomes possible for the configuration using the memory cell disclosed in the second non-patent document to ensure sufficient number of bits, and thus the problems of the above-described first non-patent document are solved.

However, in either case where an FF or an SRAM memory cell is used, if data generated using these configurations is used for random numbers, calculation data, authentication data, etc., in encryption processing, the data is often security information. Accordingly, it is necessary to employ a configuration that does not easily allow the generated data to be exposed outside. Accordingly, if a dedicated circuit for obtaining random numbers is provided using an FF and an SRAM memory cell with the processing configuration as shown in the above-described non-patent documents, and a secure circuit is used for the dedicated circuit so that the data is not exposed outside, an increase in the area of the integrated circuit and an increase in cost are brought about.

### SUMMARY OF THE INVENTION

The present invention has been made in view of the above-described circumstances, for example. It is desirable to provide a semiconductor integrated circuit, information processing apparatus and method, and program capable of generating data, such as random numbers, an ID, etc., using flip-flops (FFs) in an existing device without providing a new flip-flop (FF) circuit.

According to an embodiment of the present invention, there is provided a semiconductor integrated circuit including: a plurality of flip-flops connected to a scan chain set as a test path of an integrated circuit; and a data-collection section inputting setting values of the plurality of flip-flops connected to the scan chain through the scan chain or an independent connection path, wherein the data-collection section inputs the setting values of the flip-flops at the time the power has been turned on to the plurality of flip-flops, and performs generation processing of random numbers, or random-number generation data, or fixed data on the basis of the input values.

Further, the above-described embodiment may further include a control section performing control of changing a scan-test mode for performing scan test through the scan chain and a data collection mode for performing data collection through the scan chain, wherein the data-collection section inputs the setting values of the flip-flops in accordance with a change to the data collection mode in the control section.

Further, in a semiconductor integrated circuit according to the above-described embodiment, the control section may have a configuration capable of supplying power to the plurality of flip-flops connected to the scan chain in advance, and turning-on-power processing to the plurality of flip-flops is performed under the control of the control section.

Further, in a semiconductor integrated circuit according to the above-described embodiment, the data-collection section may generate the fixed data by selecting a setting value corresponding to a specific flip-flop from the setting values of the plurality of flip-flops at the time of turning on the power.

Further, in a semiconductor integrated circuit according to the above-described embodiment, the data-collection section may generate or hold flip-flop determination data discriminating a fixed-value-setting flip-flop holding a fixed setting value at power-on time and an uncertain-value-setting flip-flop at power-on time, and the data-collection section selectively may obtain only a setting value of a fixed-value-setting flip-flop from the setting values of the plurality of flip-flops at power-on time by applying the flip-flop determination data, and may generate the fixed data from the obtained data.

Further, in a semiconductor integrated circuit according to the above-described embodiment, the data-collection section may generate the fixed data as identification information (ID) corresponding to the semiconductor integrated circuit.

Further, in a semiconductor integrated circuit according to the above-described embodiment, the data-collection section may perform processing supplying a value generated by inputting the flip-flop setting value to data processing section included in the semiconductor integrated circuit.

Further, according to another embodiment of the present invention, there is provided an information processing apparatus including the above-described semiconductor integrated circuit.

Further, according to another embodiment of the present invention, there is provided a method of processing information in an information processing apparatus, the method including the steps of: a data-collection section inputting setting values at power-on time of a plurality of flip-flops connected to a scan chain set as a test path of an integrated circuit through the scan chain or an independent connection path; and the data-collection section performing generation processing of random numbers, or random-number generation data, or fixed data on the basis of the input values including setting values of the flip-flops at the time the power has been turned on to the plurality of flip-flops.

Further, according to another embodiment of the present invention, there is provided a program for performing information processing in an information processing apparatus, the program including the steps of: a data-collection section inputting setting values at power-on time of a plurality of flip-flops connected to a scan chain set as a test path of an integrated circuit through the scan chain or an independent connection path; and the data-collection section performing generation processing of random numbers, or random-number generation data, or fixed data on the basis of the input values including setting values of the flip-flops at the time the power has been turned on to the plurality of flip-flops.

In this regard, a program according to the present invention is a program that can be provided to, for example, an image processing apparatus or a computer system capable of executing various kinds of program code in a computer-readable format through a recording medium or a communication medium. By providing such a program in a computer readable format, processing in accordance with the program is performed on the image processing apparatus or the computer system.

The above described and other problems to be addressed, and the features and advantages of the present invention will become apparent by the below-described embodiments of the present invention and the detailed description thereof with reference to the accompanying drawings. In this regard, in the present specification, a system is a logical set of a plurality of apparatuses, and the apparatuses having individual components are not necessarily contained in a same case.

By an embodiment of the present invention, a data collection section is provided in order to input flip-flop setting values at power-on time from a plurality of flip-flops connected to the scan chain that is set as a test path of an integrated circuit, such as an LSI, etc. The data collection section inputs flip-flop setting values at power-on time through a scan chain or an independent connection path, and performs generation processing of random numbers or an ID as fixed data on the basis of the input values. With this configuration, it becomes possible to generate random numbers and an ID using the existing flip-flops formed on an integrated circuit, such as an LSI, etc., without change.

### BRIEF DESCRIPTION OF THE DRAWINGS

FIG. 1 is a diagram illustrating a structure of a D flip-flop (D-FF);

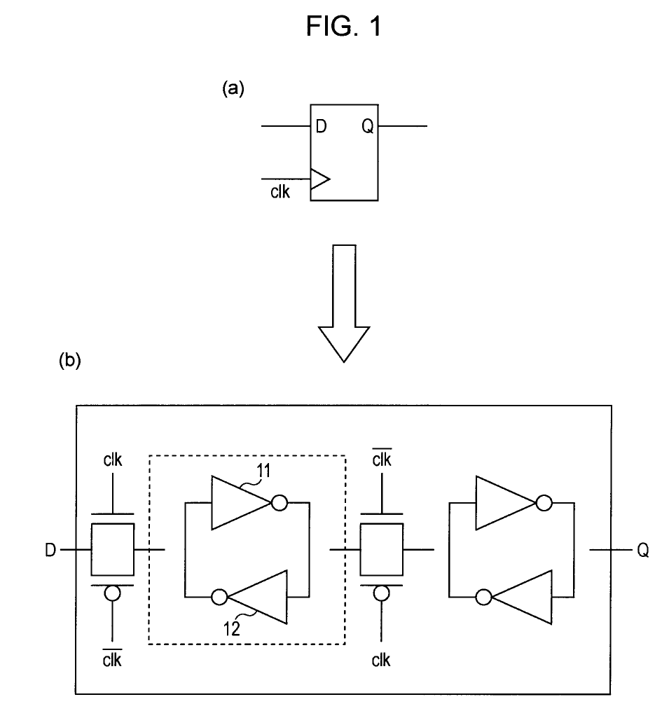

FIG. 2 is a diagram illustrating a structure of a memory cell of an SRAM;

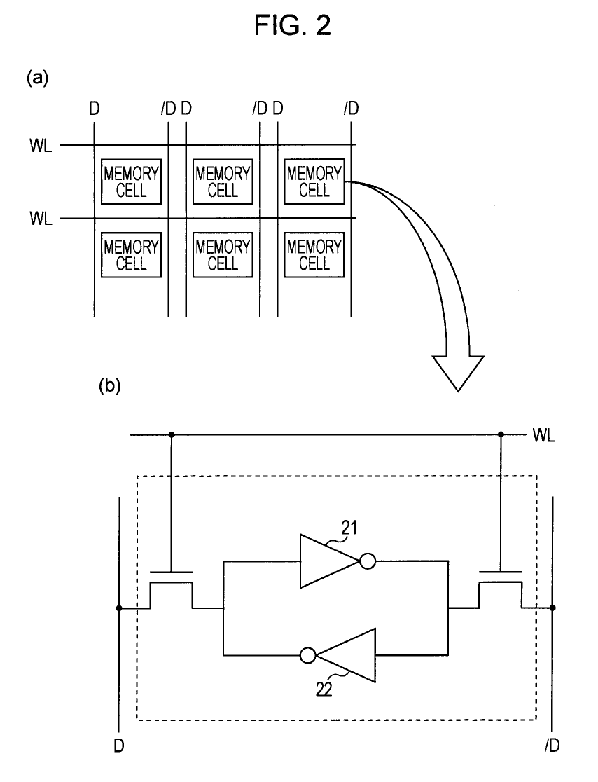

FIGS. 3A and 3B are diagrams illustrating a structure including inverters connected with each other, which is common to a flip-flop (FF) and an SRAM cell;

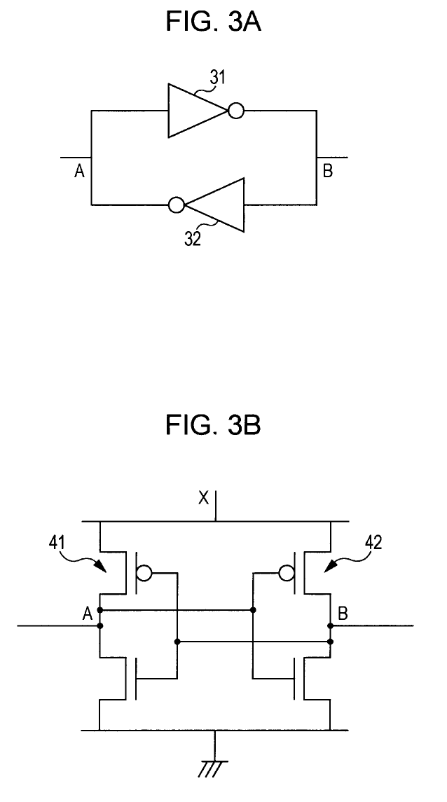

FIG. 4 is a diagram illustrating an example of a configuration of an LSI as an example of a semiconductor integrated circuit;

FIG. 5 is a diagram illustrating an example of a configuration of a semiconductor integrated circuit according to the present invention;

FIG. 6 is a flowchart illustrating data-generation-processing sequence to which a semiconductor integrated circuit according to the present invention is applied;

FIG. 7 is a diagram illustrating a specific example of generation of random numbers and an ID, and use processing thereof;

FIG. 8 is a diagram illustrating an example of a configuration and processing of pseudo-random-number generation section;

FIG. 9 is a diagram illustrating ID-generation processing and use processing;

FIG. 10 is a diagram illustrating an example of a configuration of a data-collection section;

FIG. 11 is a diagram illustrating a specific example of processing performed by a data extraction section of the data-collection section;

FIG. 12 is a diagram illustrating a specific example of processing performed by a data extraction section of the data-collection section;

FIG. 13 is a diagram illustrating a specific example of a configuration and processing of a post-processing section of the data-collection section;

FIG. 14 is a diagram illustrating a specific example of a configuration and processing of a post-processing section of the data-collection section;

FIG. 15 is a diagram illustrating a specific example of a configuration and processing of a post-processing section of the data-collection section;

FIG. 16 is a diagram illustrating an example of a configuration of a semiconductor integrated circuit according to the present invention;

FIG. 17 is a diagram illustrating an example of a configuration of a semiconductor integrated circuit according to the present invention; and

FIG. 18 is a flowchart illustrating data-generation-processing sequence to which a semiconductor integrated circuit according to the present invention is applied.

### DESCRIPTION OF THE PREFERRED EMBODIMENTS

In the following, a detailed description will be given of a semiconductor integrated circuit, information processing apparatus and method, and program according to an embodiment of the present invention with reference to the drawings. The description will be given in accordance with the following items.

1. About scan test in semiconductor integrated circuit

2. About a semiconductor integrated circuit according to an embodiment of the present invention

3. About data-generation processing sequence

4. About example of generation processing of random numbers and ID information, and use processing

5. About detailed configuration of data collection section

6. About the other examples of configuration

6.1 Example of using an FF connection path different from scan chain

6.2 Embodiment in which power-supply configuration is changed

1. About Scan Test in Semiconductor Integrated Circuit

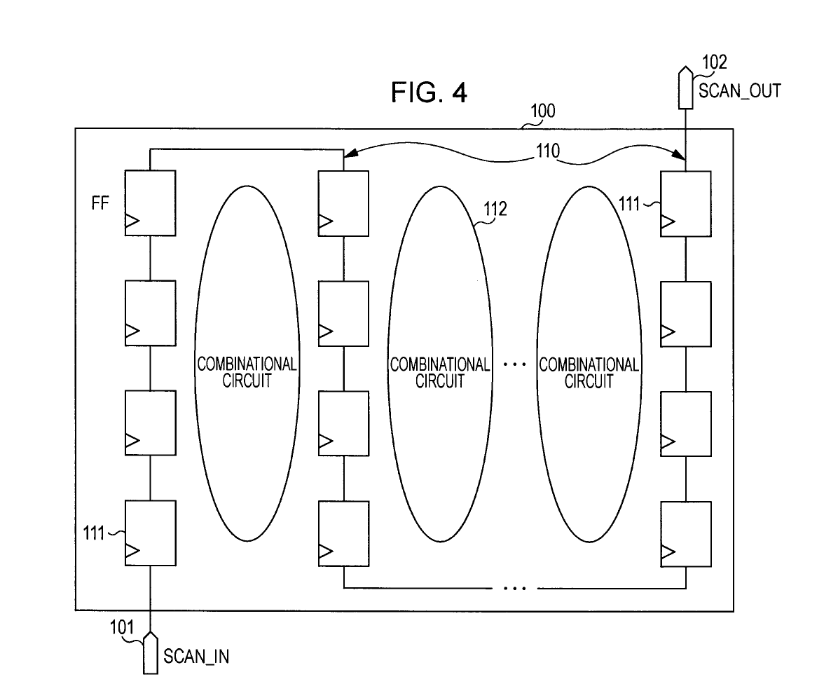

FIG. 4 illustrates an LSI 100 as an example of a semiconductor integrated circuit. The LSI 100 has a combinational circuit 112 including various circuit elements performing data processing, such as calculation, etc. Further, a large number of flip-flops (FFs) 111 to be used for a register, a cache memory, etc., are formed on the LSI 100.

As shown in FIG. 4, a scan chain 110 connecting a large number of flip-flops (FFs) 111 formed inside the chip with a connecting line irrelevant to practical wire connections is formed on an LSI chip or an IC chip as a semiconductor integrated circuit. Data is transferred between the FFs using the scan chain 110 formed as a connection component of the flip-flops (FFs) 111 so that it becomes possible to directly control and observer the state of the FFs in order to detect physical failure of the circuit. In this manner, the scan chain is used as a test circuit at a manufacturing stage and a design stage of an LSI or an IC chip.

The FFs 111 connected by the scan chain 110 can be operated as one large shift register so that it is possible to input (scan in) test patterns from an input section (SCAN_IN) 101 to each FF to which a node to detect a failure is connected. Then, the circuit is operated by a system clock, so that an expected value of the FF having a changed state can be output (scan out) from an output section (SCAN_OUT) 102. By verifying the output value, it becomes possible to conduct a circuit test, such as determination of a failed part.

The scan chain 110 is connected to almost all the FFs included in the LSI for the purpose of verification of the circuit. In this regard, in the following, a description will be given of an example using an LSI as an example of a semiconductor integrated circuit. However, the present invention is not limited to an LSI, but can be applied to an IC chip on which a plurality of FFs are formed, and a semiconductor integrated circuit.

The number of FFs connected to the scan chain depends on the size of an LSI and its packaging, and thus is difficult to be exhibited specifically. However, in the present circumstances, an LSI having a size of about one million gates is provided. Thus, it is easily assumed that an LSI contains a very large number of FFs. In this regard, a very log scan chain increases testing time, and thus a scan chain divided into a plurality of pieces are sometimes packaged.

2. Semiconductor Integrated Circuit According to an Embodiment of the Present Invention

The circuit shown in FIG. 4 has a general circuit configuration in a digital circuit. A connection configuration from an input section (SCAN_IN) 101 to an output section (SCAN_OUT) 102 represents a scan chain 110.

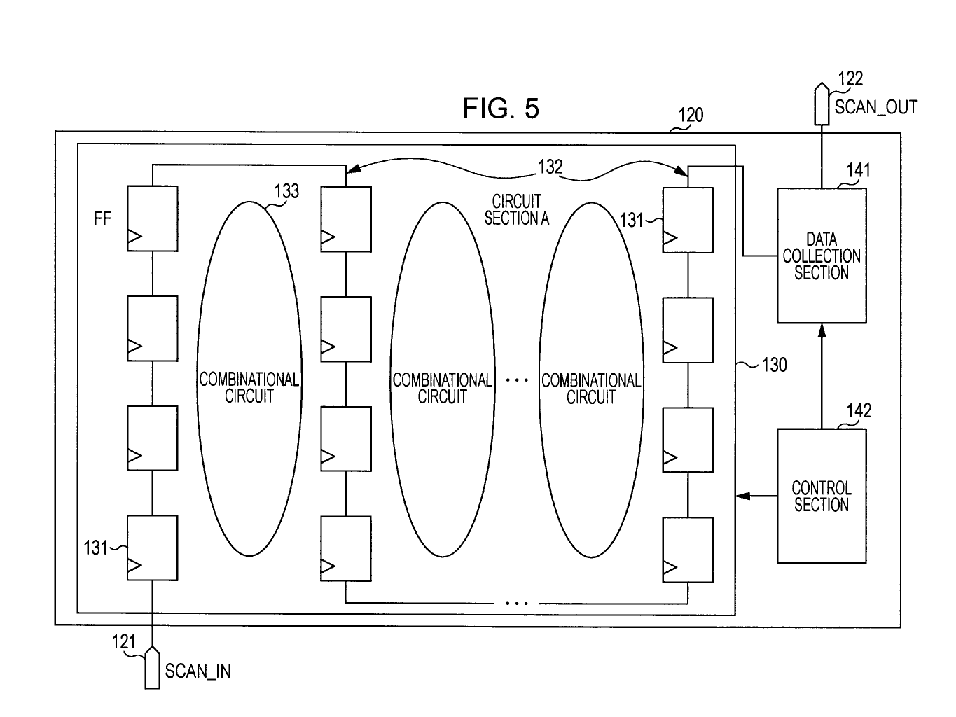

A description will be given of an example of a configuration of a semiconductor integrated circuit according to the present invention with reference to FIG. 5. In the LSI 120 shown in FIG. 5, a circuit section 130 has a same circuit configuration as that described before with reference to FIG. 4. That is to say, the LSI 130 has a combinational circuit 133 including various circuit elements performing data processing. Further, the LSI 130 has a large number of flip-flops (FFs) 131 to be used for a register, a cache memory, etc. A large number of flip-flops (FFs) 131 are connected through wires, and form a scan chain 132. The scan chain 132 is provided as a test path for the integrated circuit.

The LSI 120 according to the present invention has a data collection section 141 for collecting values of the FFs connected through the scan chain 132 in the middle of the scan chain 132 or at a final output section. Further, the LSI 120 has a control section 142 for controlling a change of wiring between a scan operation (scan mode) and a normal LSI operation (LSI operation mode), and for controlling operation of data collection section 141.

In the same manner as the above-described circuit shown in FIG. 4, test processing using the scan chains 132 is performed by inputting (scan in) test patterns from an input section (SCAN_IN) 121 to each FF from which a failure is detected. Next, the circuit is operated by a system clock so that an expected value of the FF having a changed state can be output (scan out) from an output section (SCAN_OUT) 122. Thereby, it is possible to verify a failure.

The configuration shown in FIG. 5 is an example in which the data collection section 141 is provided at a final output section of the scan chain 132. That is to say, the data collection section 141 is disposed before the output section (SCAN_OUT) 122.

The data collection section 141 obtains values of the FFs 131 connected by the scan chain 132 in the LSI 120 through the scan chain 132. For example, the data collection section 141 collects FF setting values at power-on time. The FF setting values at power-on time include many uncertain values. As described before, flip-flops (FFs) sometimes have a random value, which is a value not fixed to either 1 or 0, at power-on time. The data collection section 141, for example collects the setting values of such a plurality of the flip-flops (FFs) at power-on time through a scan chain. The collected values are used for random numbers and an ID.

As described above, flip-flops (FFs) have different characteristics for individual elements. Flip-flops (FFs) can be classified into the following two kinds of elements in accordance with a mode of an initial setting value at power-on time.

(a) An element indicating random uncertain values: uncertain-value-setting element (uncertain-value-setting FF)

(b) An element indicating a fixed value all the time: fixed-value-setting element (fixed-value-setting FF)

FFs can be classified into the two kinds of elements.

This is determined on the basis of the threshold values and the physical conditions of both of the PMOSs.

A value obtained from the uncertain-value-setting element (uncertain-value-setting FF), which indicates a different setting value each power-on time, can be used for random numbers to be applied to, for example, calculation processing, encryption processing, etc.

Also, a value obtained from the fixed-value-setting element (fixed-value-setting FF), which indicates a fixed value each power-on time, can be used for, for example, an ID relating to an LSI chip, etc.

In this regard, when a value collected by the data collection section 141 is used for random numbers and an ID corresponding to an LSI chip, etc., processing is performed so that the value obtained by the data collection section 141 is output to a calculation circuit or a memory, etc., in the LSI 120 and used. A description will be given later of this processing configuration.

A very large number of FFs in an LSI chip are connected to the scan chain, and thus it is possible to obtain data of sufficient number of bits without increasing a chip area. For example, it is possible to obtain a value represented by a bit string including tens of bits to thousands of bits. Thus, it is possible to generate and use random numbers and an ID using the obtained value.

A connection between the data collection section 141 and the scan chain 132 can be made in various ways. In the example shown in FIG. 5, one scan chain is input into the data collection section 141. For example, a plurality of scan chains are sometimes disposed in order to conduct a test efficiently. If a plurality of scan chains are disposed on an LSI, the data collection section may collect data of the plurality of scan chains in parallel or selectively. If the data collection section is configured to receive input data of a plurality of scan chains, a merge processing section can be disposed in the data collection section, and input data from the individual scan chains are merged, and the result of the merge can be used as random numbers and an ID.

3. About Data-Generation Processing Sequence

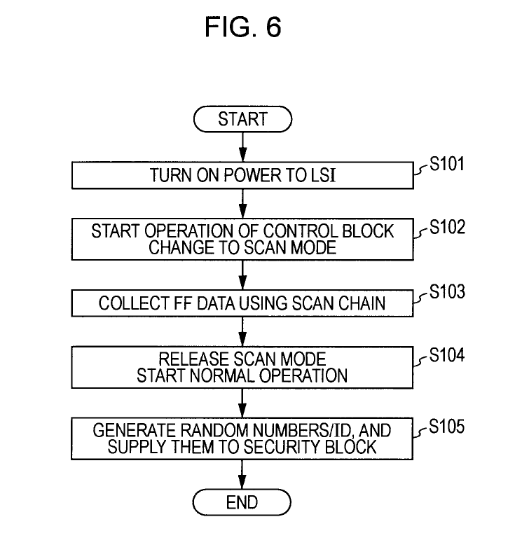

Next, a description will be given of a data-generation processing sequence to which a semiconductor integrated circuit, for example having the configuration shown FIG. 5, according to the present invention is applied with reference to a flowchart shown in FIG. 6.

In step S101, power to the LSI 120 is turned on. The individual FFs hold initial setting value 0 or 1 in the FFs depending on the difference in the individual physical conditions.

In step S102, operation of the control section 142 is started. The control section 142 changes the mode of the FFs to the scan mode so that the scan chain 132 can be used.

In step S103, the held data of the flip-flops (FFs) connected to the scan chain 132 is input into the data collection section 141 through the scan chain 132. The data collection section 141 performs necessary processing internally in accordance with either of the purposes, random-number generation or ID generation, and then outputs or holds the data.

In step S104, after the data collection section 141 has collected data, the control section 142 releases the scan mode, resets to initialize the FFs, and changes the mode to a normal LSI operation mode.

In step S105, in a state of the LSI operation mode, the data obtained by the data collection section in step S104 is supplied to a security block in the LSI 120, and is used for random numbers, or random-number generation data, or an ID, for example a specific value (ID) applied to an LSI chip identifier, etc., and the like.

In this regard, as described above, the flip-flops (FFs) have different element characteristics individually, and include elements having random initial setting values at power-on time, and elements having a fixed value at that time. That is to say, there are two kinds of elements as follows:

(a) An element indicating random uncertain values: uncertain-value-setting element (uncertain-value-setting FF)

(b) An element indicating a fixed value all the time: fixed-value-setting element (fixed-value-setting FF)

If the data obtained by the data collection section is applied as random numbers, it is possible to use mixed data of the output values of the above described two kinds of elements. However, if the data is used as an ID, it is necessary that the data is fixed data all the time. Accordingly, it is necessary to select data obtained from a specific fixed-value-setting element (fixed-value setting FF). A description will be given of this processing later.

4. About Example of Generation Processing and Use Processing of Random Numbers and ID Information

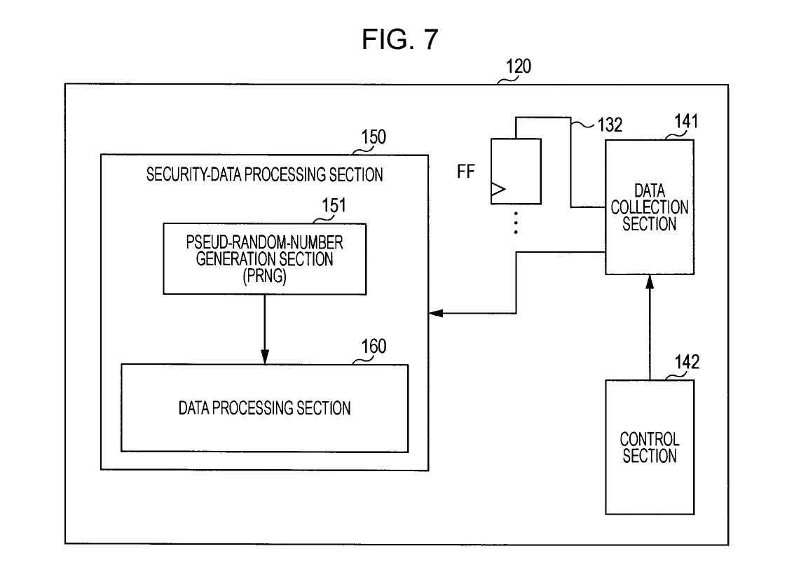

Next, with reference to FIG. 7 and subsequent figures, a description will be given of a specific example of generation and use processing of random numbers and an ID in step S105 in the processing described with reference to FIG. 6.

4.1 About Random-Number Generation Processing and Use Processing

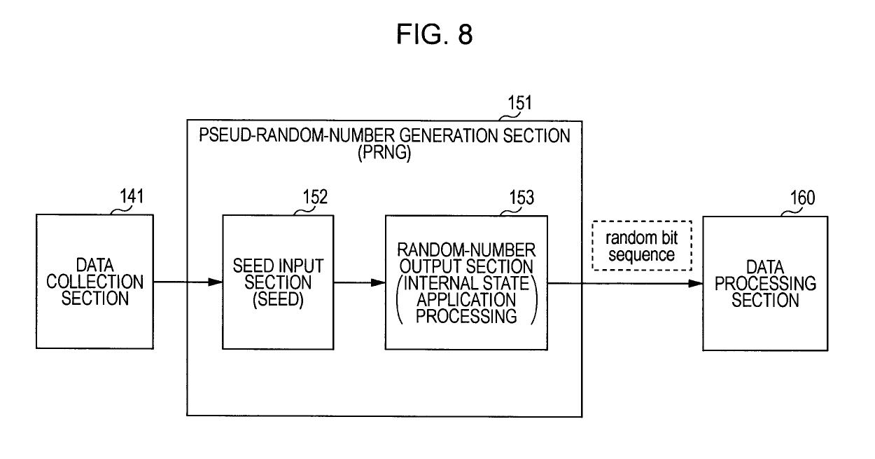

First, a description will be given of the random-number generation processing and the use processing with reference to FIGS. 7 and 8. The LSI 120 shown in FIG. 7 is the same LSI as the LSI 120 shown in FIG. 5. Only component sections related to the Random-Number generation processing is shown in the figure.

The data collection section 141 inputs the FF setting values to the LSI 120 at power-on time through the scan chain 132. Data having a bit length for the number of the FFs connected to the scan chain is input into the data collection section 141. For example, if 100 FFs are connected to the scan chain, 100-bit data is input into the data collection section 141.

The data collection section 141 supplies the data input from the scan chain 132 to a security-data processing section 150. The security-data processing section 150 has a pseudo-random-number generation section (PRNG: pseudo-random-number Generator) 151 performing random-number generation processing. In the security-data processing section 150, the input data from the data collection section 141 is input into the pseudo-random-number generation section (PRNG) 151, and random-number generation processing is performed. The generated random numbers are output to the data processing section 160. The data processing section 160 performs processing, such as public-key encryption, or digital signature algorithm, or authentication protocol, etc., for example.

A description will be given of the configuration and the processing of the pseudo-random-number generation section (PRNG) 151 with reference to FIG. 8. A seed input section 152 of the pseudo-random-number generation section (PRNG) 151 inputs a seed to be used for random-number generation from an input bit string from the data collection section 141.

The random-number output section 153 inputs a seed from the seed input section 152, and applies a predetermined pseudo-random-number generation algorithm to generate and output random numbers having a predetermined number of bits. For example, the random-number output section 153 updates an internal state in accordance with a predetermined algorithm using the seed as an initial value, and continuously generates a random-number bit string (a random bit sequence), and outputs it to the data processing section 160.

4.2 About ID-Generation Processing and Use Processing

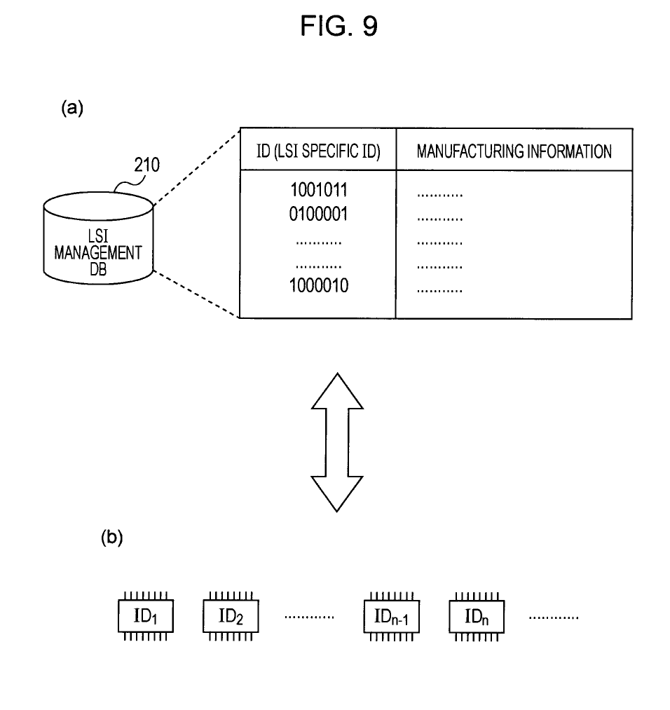

Next, a description will be given of the ID-generation processing and the use processing with reference to FIG. 9. A description will be given of an example of processing in which the data obtained by the data collection section from a plurality of FFs through the scan chain is used as an ID. In this regard, if the data is used as an ID, it is necessary that the data is fixed data all the time so that data obtained from a specific fixed-value-setting element (fixed-value setting FF) is selected and used. A description will be given later of this processing. First, an example of using an ID is described with reference to FIG. 9.

An ID is set in relationship to each LSI, for example as an LSI specific identifier (ID), and is managed in an LSI-management database 210 as shown in FIG. 9 by relating an ID and manufacturing information, etc. This data can be used, for example for management information in an LSI manufacturing factory, etc.

The example shown in FIG. 9 is an example in which LSI-specific management information relating an LSI-chip specific ID and manufacturing information is generated and managed in the LSI management database 210 as shown in FIG. 9(a) in an LSI manufacturing factory. As shown in FIG. 9(b), a large number of LSI chips are manufactured. An LSI-chip ID is determined to be a bit string including FF setting values collected by the data collection section 141 through the scan chain 132 connecting the FFs in the individual LSI chips. This ID is stored in the database 210 in relationship to the manufacturing information.

In this manner, an LSI specific ID is obtained at LSI manufacturing time, and is tied to manufacturing information so that the information can be used for failure analysis after chip shipment. Also, for another use, it is also possible to use an ID as a key for encryption of secret information and authentication for each chip. Further, it is also possible to use an ID as license information in the case of providing an LSI-mounted PC, etc., with an application program, for example. That is to say, an ID can be used as hardware specific information.

5. About Detailed Configuration of Data Collection Section

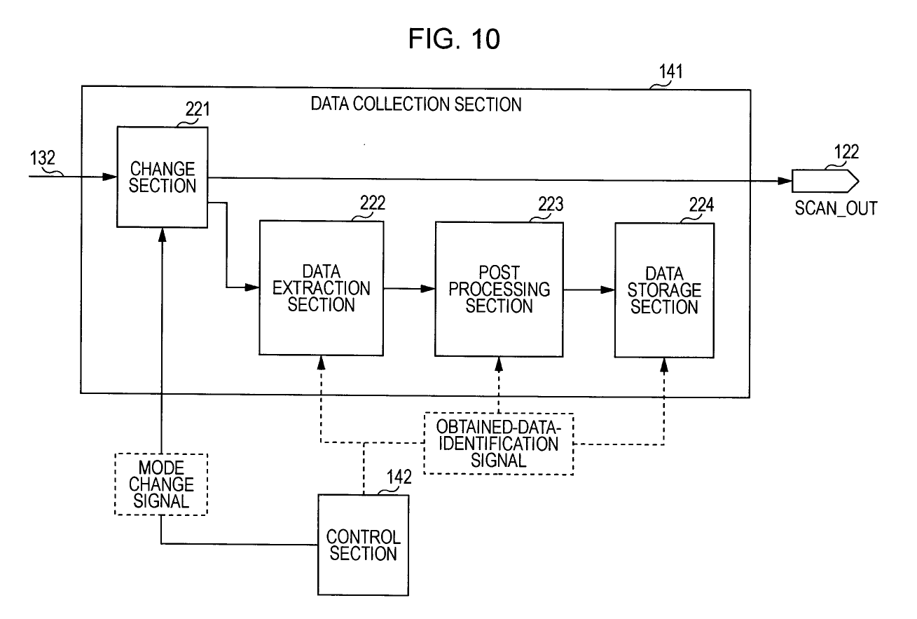

Next, a detailed description will be given of the configuration and the processing of the data collection section 141 shown in FIG. 5. An example of the configuration of the data collection section 141 is shown in FIG. 10.

As shown in FIG. 10, the data collection section 141 has a change section 221, a data extraction section 222, a post-processing section 223, and a data storage section 224.

The change section 221 changes an output destination of the input data from the scan chain 132 in accordance with the mode by receiving the mode-change signal from the control section 142. That is to say, if the mode is set to the data collection mode, the change section 221 outputs the input data from the scan chain 132 to the data extraction section 222.

If the mode is set to the scan test mode, the change section 221 outputs the input data from the scan chain 132 to the output section (SCAN_OUT) 122.

If the mode is set to the data collection mode, the change section 221 performs output control so that the collection data is not allowed to be observed from the outside through the output section (SCAN_OUT) 122 in accordance with the mode change.

If the mode is set to the data collection mode, the change section 221 outputs the input data from the scan chain 132 to the data extraction section 222.

The data extraction section 222 is a block which obtains necessary data from the bit string being sent through the scan chain 132.

The post-processing section 223 is a function having a function of processing the data sequence collected through the scan chain 132 into data necessary for random number generation or chip-ID generation. That is to say, the post-processing section 223 performs processing of the data sequence made of a bit string including setting values of the FFs in the order of the connection to the scan chain 132 into data necessary for random-number generation or chip-ID generation.

Also, the data storage section 224 has a function of holding the data processed by the post-processing section 223, that is to say, random numbers and an ID. The data storage section 224 has a function of holding the data using, for example, FFs without rest, a nonvolatile memory, and a volatile memory in accordance with the amount of data necessary for acquisition.

In this regard, the data extraction section 222, the post-processing section 223, and the data storage section 224 sometimes perform different processing depending on whether the data collected through the scan chain 132 is used for random numbers or an ID. The data extraction section 222, the post-processing section 223 and the data storage section 224 receives the input of an acquisition-data-identification signal from the control section 142, and changes the processing mode. In this regard, either one of the processing may be set to be performed in accordance with the LSI chip, that is to say, random-number generation or ID acquisition as fixed data may be performed. In such a case, the data extraction section 222, the post-processing section 223, and the data storage section 224 can perform fixed processing, and thus the acquisition-data-identification signal from the control section 142 is unnecessary.

In the following, a description will be given of an example of specific processing of the data extraction section 222, the post-processing section 223, and the data storage section 224.

Processing of Data Extraction Section 222

The data extraction section 222 is a block which obtains necessary data from the bit string being sent through the scan chain 132.

As described before, the flip-flops (FFs) have different element characteristics individually, and include elements having random initial setting values at power-on time, and elements having a fixed value at that time. That is to say, there are two kinds of elements as follows:

(a) An element indicating random uncertain values: uncertain-value-setting element (uncertain-value-setting FF)

(b) An element indicating a fixed value all the time: fixed-value-setting element (fixed-value-setting FF)

If the data obtained by the data collection section is applied as random numbers, it is possible to use mixed data of the output values of the above described two kinds of elements. However, if the data is used as an ID, it is necessary that the data is fixed data all the time. Accordingly, it is necessary to select data obtained from a specific fixed-value-setting element (fixed-value setting FF).

The data extraction section 222 receives the data sequence made of a bit string including FF setting values arranged in the order of the connection to the scan chain 132. The data sequence is a data string with mixed bit values of uncertain-value-setting elements (uncertain-value-setting FFs) and fixed-value-setting elements (fixed-value-setting FFs).

If random numbers are obtained or generated, it is possible to use the mixed data of the bit values of uncertain-value-setting elements (uncertain-value-setting FFs) and fixed-value-setting elements (fixed-value-setting FFs). However, if an ID is obtained, it becomes necessary to perform processing to select and obtain only the bit values of fixed-value setting elements (fixed-value setting FFs).

Accordingly, if the obtained data is used for random number generation, etc., the data extraction section 222 extracts data of a necessary number of bits, and outputs the data to the post-processing section 223 without selecting data to be obtained from the scan chain 132.

On the other hand, if the obtained data is used for an ID, etc., the data extraction section 222 selects and obtains only bit values of fixed-value-setting elements (fixed-value-setting FFs) from the data obtained from the scan chain 132, and outputs the bit values to the post-processing section 223.

The data extraction section 222 performs either of the two kinds of different processing in accordance with the obtained data.

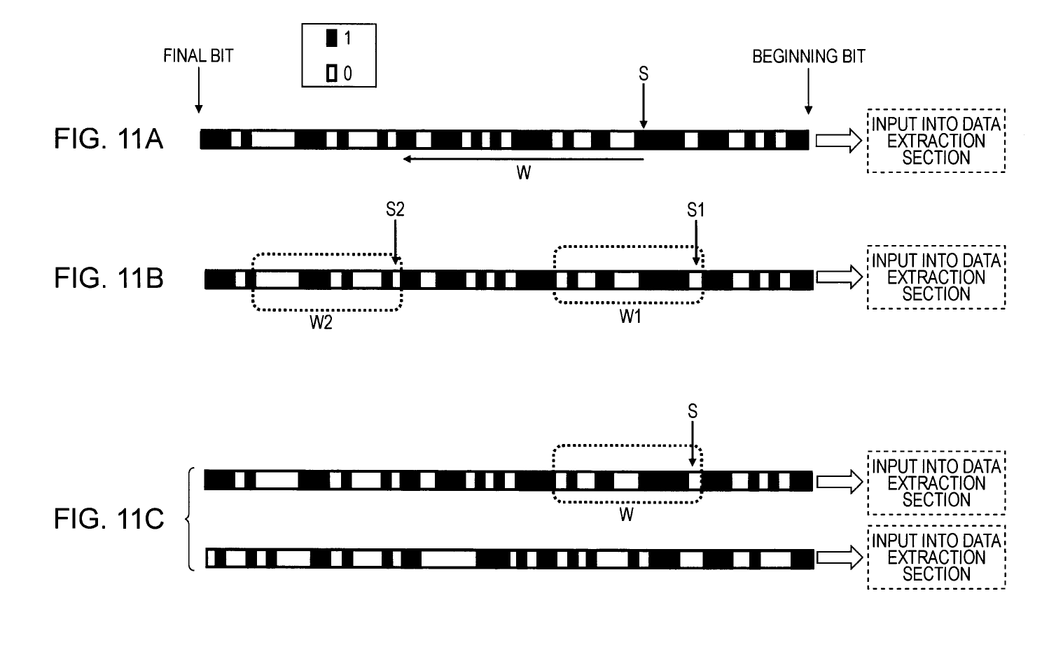

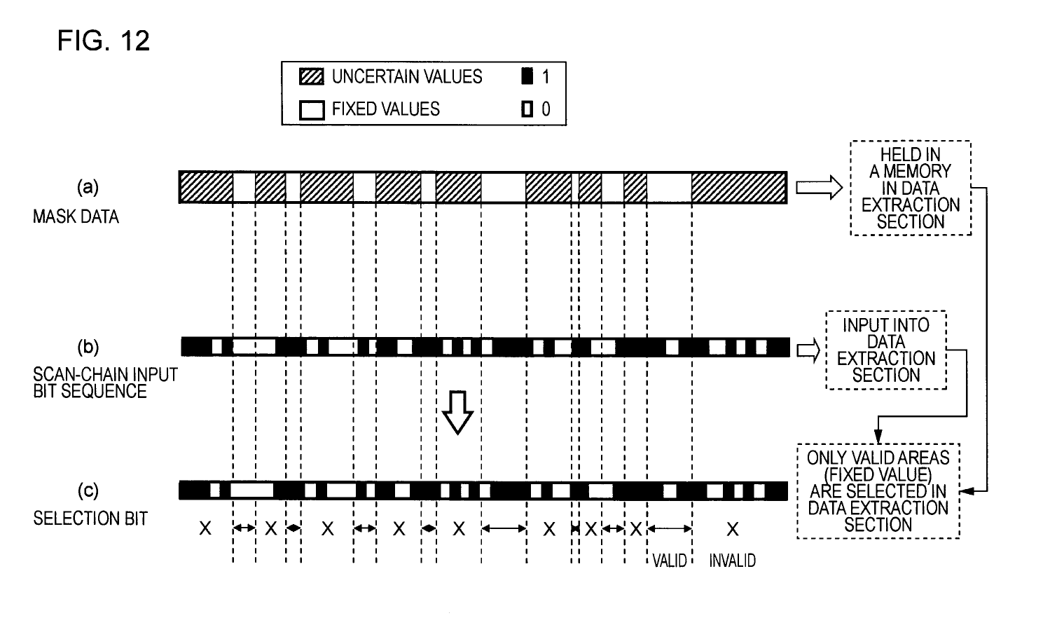

In the following, a description is given of two specific examples of the processing with reference to FIGS. 11 and 12.

FIG. 11 is a diagram illustrating an example of processing of the data extraction section 222 in the case where the obtained data is used for random number generation, etc. That is to say, the data extraction section 222 extracts data of a necessary number of bits, and outputs the data to the post-processing section 223 without selecting data to be obtained from the scan chain 132.

FIG. 11A illustrates an example of a data sequence to be obtained from the scan chain 132. The figure represents a bit string including continuous 0 or 1, a black cell represents 1, and a white cell represents 0. The right end is a beginning bit of a scan chain, and the left end is a final bit of the scan chain.

In this example, it is not necessary to distinguish the bit values of uncertain-value-setting elements (uncertain-value-setting FFs) and fixed-value-setting elements (fixed-value-setting FFs) from the data sequence obtained from the scan chain 132. The extraction block performs processing to extract a necessary bit size (W) necessary for the post-processing block in the subsequent stage from a bit-value-acquisition start position (S) simply determined by a designer.

The cutting-out processing may be performed by collecting a bit string starting from one start position of the bit string, for example as shown in FIG. 11A, or may be performed by collecting bit strings from a plurality of start position as shown in FIG. 11B.

Also, as described before, a plurality of independent scan chains are sometimes set on an LSI. In this case, as shown in FIG. 11C, a bit string to be obtained may be selectively extracted from a plurality of scan paths. Also, Figs. A, B, and C are suitably combined to be extracted. In this manner, a bit string having an extracted bit size (W) is output to the post-processing section 223.

Next, a description is given of the processing of the case of generating fixed data, for example an ID from the scan chain with reference to FIG. 12. In this case, the data extraction section 222 performs processing for selecting only the bit values of the fixed-value setting elements (fixed-value setting FFs) from the input values of the scan chain.

If this processing is performed, a plurality of times of power-on processing is performed for example, at LSI-chip manufacturing time, etc., as pre-processing so that verification processing is performed to find out at which position FFs indicating fixed values are disposed for each power-on processing. That is to say, detection processing on whether a plurality of the FFs connected to the scan chain are fixed-value-setting elements (fixed-value setting FFs) or not ought to be performed in advance. The position data of the fixed-value setting FFs is held in the nonvolatile memory, etc.

Data shown in FIG. 12(a) is mask data generated by the pre-processing. That is to say, the data is flip-flop determination data discriminating a fixed-value setting flip-flop holding a fixed setting value at power-on time and an uncertain-value setting flip-flop holding an uncertain setting value at power-on time.

In the mask data, positions of fixed-value setting FFs are denoted by “white”, and positions of uncertain-value-setting FFs are denoted by “hatched lines”. The mask data is held in the volatile memory, etc., in the data extraction section 222.

FIG. 12(b) shows a bit sequence input from the scan chain 132 in the case of obtaining an ID. The data extraction section 222 selects only bit values of the positions of fixed-value-setting FFs from the input bit sequence. The mask data shown in (a) is used for the selection processing. The white parts in the mask data shown in (a) are the positions of the fixed-value setting FFs, and the fixed-value data is obtained by using only these parts.

As a result, data of only an effective area shown in FIG. 12(c) is obtained. The effective area data is the bit data disposed at the position of the fixed-value setting FFs. Accordingly, it is possible to obtain data including a fixed bit value all the time. In this regard, if the obtained data is used for an ID, for example, data having a fixed bit length from a fixed start position is selected from the effective area in FIG. 12(c).

By this processing, it becomes possible to obtain the same fixed bit string all the time, and to use the data as an ID of an LSI chip, for example.

In this regard, the example in FIG. 12 is an example in which only bit data at the position of the fixed-value setting FFs is selected to be used as an ID. On the contrary, it is possible to use the data as random numbers by selecting only uncertain-value setting FFs. In this case, data of only uncertain-value-setting FFs is selected using mask data having an inverted pattern from that of the mask data shown in FIG. 12(a). In the example described with reference to FIG. 11, the data of the fixed-value setting FFs and the uncertain-value-setting FFs are mixed to be used for random numbers. By setting in such a way, it is possible to generate random numbers including only uncertain bit data of uncertain-value-setting FFs, which does not include fixed bits of the fixed-value setting FFs.

Processing of post-processing section 223

Next, a description is given of processing of the post-processing section 223 in the data collection section 141. The post-processing section 223 inputs either the random-number data or the ID data that is generated by the data extraction section 222 from the data extraction section 222. The post-processing section 223 performs different processing for generating random numbers and for generating an ID. In the following, a description will be given of the processing of the case of random number generation and the case of ID generation in sequence.

In the case of random-number generation processing

In the case of random-number generation processing, the generated random number is then supplied to the calculation processing section in the LSI, and for example is applied to calculation of encryption processing, etc. Accordingly, a necessary number of random-number bits becomes the number of bits in accordance with the number of bits for an algorithm used in the LSI.

The random numbers having a necessary number of bits for calculation processing may be formed only by the input bits from the scan chain in advance, and may be stored in the data storage section 224 of the data collection section 141. In this case, the post-processing section 223 does not perform processing on the bit string having a bit length (W) obtained by the data extraction section 222, and ought to store the bit string into the data storage section 224.

However, for example, if the bit size of the random numbers used in the algorithm performed in the LSI is large, etc., the random numbers sometimes fail to be stored in the data storage section 224. Also, it is assumed that the algorithm used in the LSI uses a plurality of different random numbers, etc.

In such a case, it is effective to have a configuration in which a bit sequence formed by the input bits from the scan chain is used for the seed data for pseudo-random-number generation. In the following, a description is given of a configuration of pseudo-random-number generation with the seed generation.

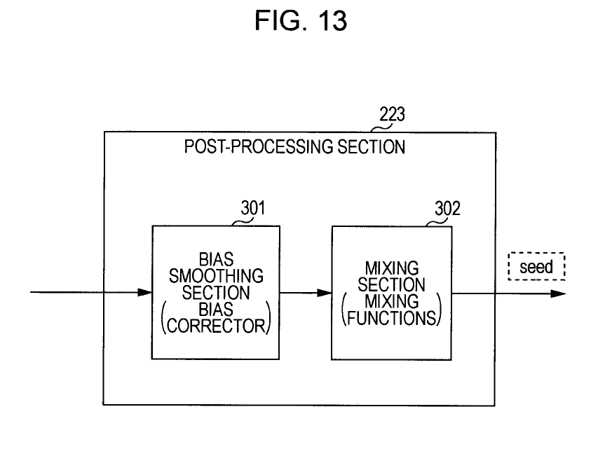

For example, a seed having about 160 bits, which is an initial value for pseudo-random-number generation (PRNG) algorithm, is generated using the input bits from the scan chain. FIG. 13 illustrates an example of a configuration of post-processing section 223 performing the seed-generation processing.

As shown in FIG. 13, the post-processing section 223 has a bias smoothing section (bias corrector) 301 performing bias smoothing processing on an output from the data extraction section 222, and a mixing section (mixing function) 302 for improving the statistical quality of an output of the bias smoothing section 301.

The bias smoothing section 301 performs processing for generating bit-string data of a predetermined size (W2) on the basis of the bit string of a predetermined size (W), which is output from the data extraction section 222. The bit size may be shortened or expanded. Various algorithms can be applied to the bit-size-conversion processing. For example, it is possible to employ a configuration for performing processing to which an existing von Neumann's algorithm is applied.

Further, the mixing section 302 compresses the bit size of the data string with a bit size (W2), which is output from the bias smoothing section 301 using a hash function and block encryption to generate a bit string of a bit size (W3) corresponding to a preset seed. The processing described in the following document can be applied to the processing, for example A. Soohoo, “Lockdown Random Numbers Secure Network SoC Designs”, CommsDesign.com, www.commsdesign.com, Apr. 1, 2003.

In this regard, the example of configuration of the post-processing section 223 shown in FIG. 13 is one example. And the other configurations may be employed as long as a seed having a predetermined bit size can be generated on the basis of the bit string input from the data extraction section 222. For example, the configuration may include only the bias smoothing section 301 or may include only the mixing section 302.

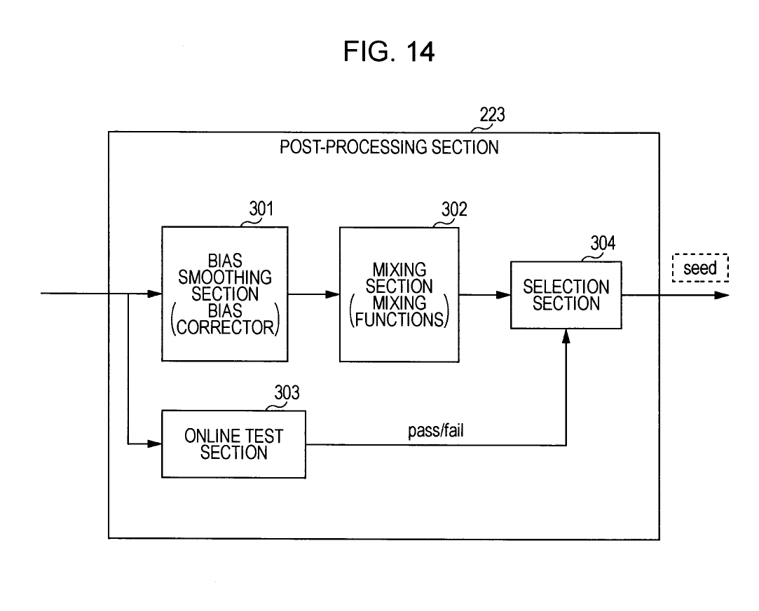

Also, for a configuration of the post-processing section 223, as shown in FIG. 14, an online test section 303 may be added in order to check the quality of the output data from the data extraction section 222.

The online test is a block in which test items set by a designer are mounted. The value that has passed this test is selected by the selection section 304, and is adopted to be a seed value. An example of the test item includes processing of observation of a bias of 0 or 1 of bit data string, observation of whether the same value continues in the data string, etc. Only in the case where a bit string that has passed a preset test result is set, the value is output as a seed value.

In the case of generation processing of fixed-data, such as ID, etc.

Next, a description is given of processing of the post-processing section 223 in the data collection section 141 in the case of generating fixed data, such as an ID, etc. When a fixed bit string, such as an ID is generated, it is necessary to perform processing such that an erroneous bit string is not produced by, for example noise, etc.

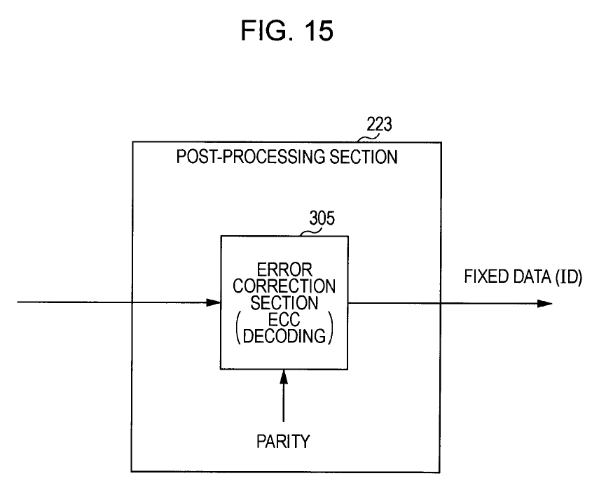

Specifically, for example, it is necessary to perform error correction on the input bit value. FIG. 15 illustrates an example of a configuration of the post-processing section 223 performing generation processing of fixed data, such as an ID, etc. The post-processing section 223 shown in FIG. 15 has an error-correction section (ECC decoding) 305.

The error correction section 305 is a block performing decoding processing (ECC decoding) by error correction on the output from the data extraction section 222. After the error correction section 305 performs error correction, the error correction section 305 outputs the data as an ID. Also, the error correction section 305 sets a parity for performing error correction in a pre-stage, such as at chip-manufacturing time, etc., and stores the data into the data storage section 224. Alternatively, the error correction section 305 stores the data into a memory formed by the other nonvolatile memories, etc.

6. About the Other Examples of Configuration

6.1 Example of Using FF Connection Path Different From Scan Chain

A description has been given of a method of using a scan chain in a design technique facilitating a test so far. However, it is possible to use a method without using an existing scan chain.

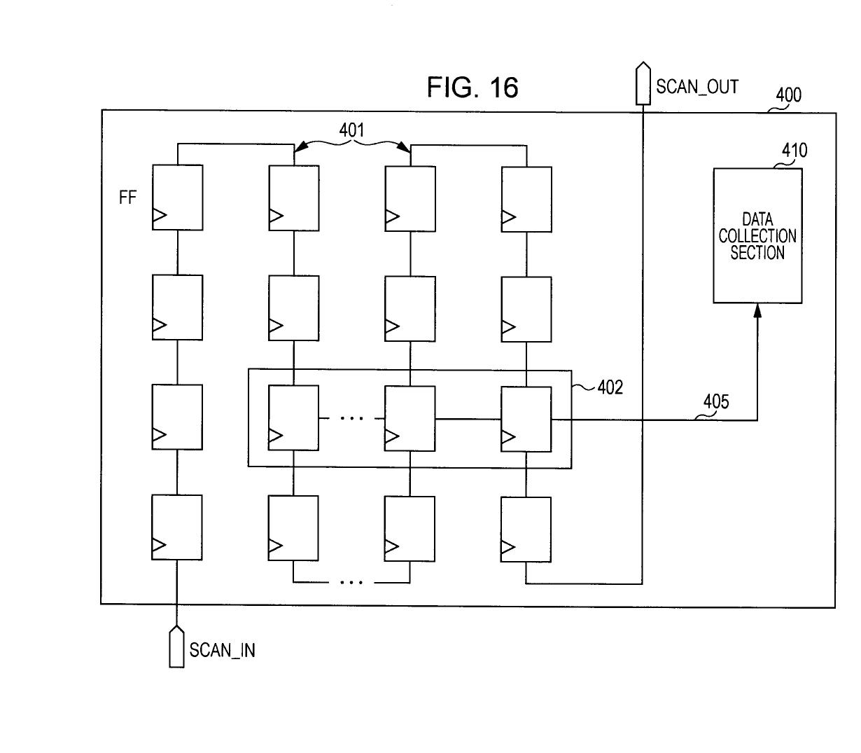

For example, as an LSI 400 shown in FIG. 16, a configuration without using an existing scan chain 401 may be employed. An FF circuit block 402 including specific flip-flops (FFs) is set, an FF connection path 405 connecting the FFs in the FF circuit block 402 is set, and the FF connection path 405 is connected to the data collection section 410. With this configuration, it becomes possible to input the setting values (setting values at power-on time) of the FFs in the FF circuit block 402.

In this regard, the configuration shown in FIG. 16 is not provided with a control section, and the data processing section 410 performs processing only at power-on time. Alternatively, it is also allowed to employ a configuration in which a control section having the same configuration as described with reference to FIG. 5 before is provided, and processing is performed in accordance with a mode change by inputting a mode-change signal under the control of the control section.

6.2 Embodiment in Which Power-Supply Configuration is Changed

As described above, in the LSI described with reference to FIG. 5 and subsequent figures, the data collection section 141 collects FF setting values at the time of starting power supply to the LSI 120 through the scan chain. However, the data collection processing by the data collection section 141 is executed substantially at the same timing with the starting power supply to the LSI 120. Also, sometimes it becomes necessary to input a control signal from the control section 142 to the data collection section 141, etc., at the same timing with or before starting the data collection. However, if power is supplied to the control section 142 at the same time, correct control might not be performed.

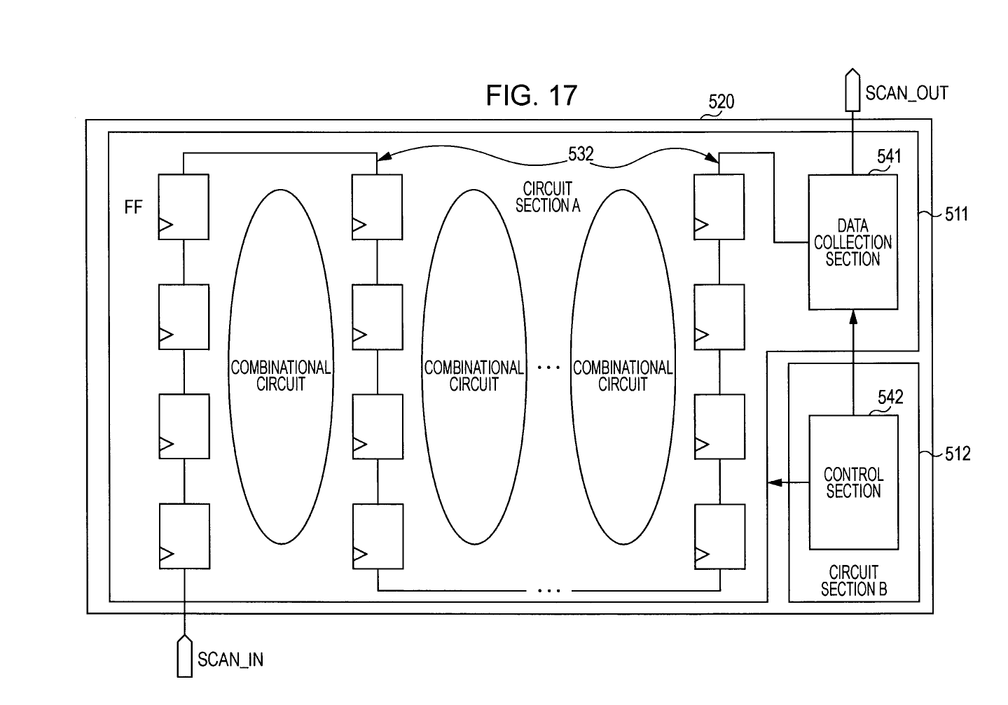

Thus, in order to solve this, a power-supply configuration for an LSI 520 is provided as shown in FIG. 17. A different power source is provided to a circuit section A 511 including a scan chain 532 and a data collection section 541 from a power source to a circuit section B 512 including a control section 542. That is to say, two systems of power sources are provided, and power supply is carried out to the circuit section B 512 corresponding to the control section 542 in advance. And, after the control of the control section 542 has reliably become an executable state, data collection processing from the scan chain 532 is started through the power supply to the circuit section A 511.

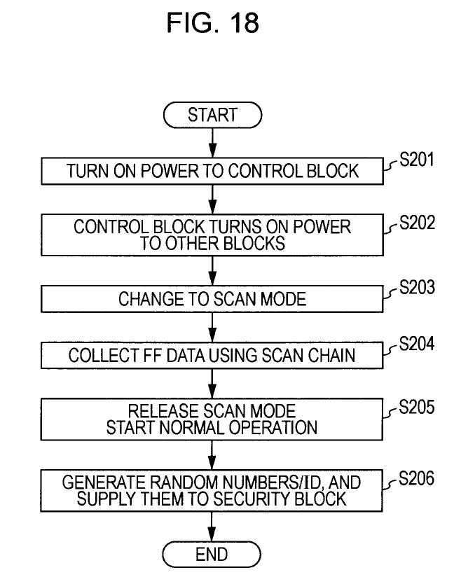

A description will be given of a processing sequence in accordance with this configuration with reference to the flowchart shown in FIG. 18.

In step S201, the power to the control block including the control section 542 is turned on.

Next, in step S202, after the control section 542 turns off the power to the circuit section A 511 or confirms the power has be turned off, the control section 542 turns on the power to the circuit section A 511. By this operation, each of the FFs included in the circuit section A 511 holds an initial setting value 0 or 1 in the FF depending on the difference in each physical condition.

In step S203, the control section 542 changes the FF mode to the scan mode in order to allow using the scan chain 532.

In step S204, the holding data of the flip-flops (FFs) connected to the scan chain 532 is input into the data collection section 541 through the scan chain 532. The data collection section 541 performs internally necessary processing in accordance with either one of the purposes, random-number generation or ID generation, and then outputs or holds the data.

In step 5205, after the data collection section 541 performs data collection, the control section 542 releases the scan mode, resets the FFs to initialize them, and changes the mode to a normal LSI-operation mode.

In step S206, the data obtained by the data collection section in step S204 in a state of being set to the LSI operation mode is supplied to the security block in the LSI 520. And the data is used for a specific value (ID), etc., to be applied to a random number, or random-number generation data, or an ID, for example, an LSI-chip identifier, etc.

In the configuration described with reference to FIGS. 17 and 18, the power is supplied to the control section 542 in advance. And after the operation of the control section 542 becomes stable, the power supply to the individual FFs of the scan chain is started, and thus it becomes possible to reliably collect the setting values of the FFs at power-on time under the control of the control section 542.

As described above, in the configuration according to the present invention, it becomes possible to perform random-number generation processing or ID-generation processing directly using the FFs mounted on an LSI chip without adding a dedicated FF, and thus it is possible to achieve a configuration preventing an increase in a chip area and an increase in cost. Also, the collection data by the data collection section can be supplied to a calculation circuit in the LSI, and there is no possibility that the collection data is mistakenly output to the outside, and thus it becomes possible to perform processing with protecting security. By using the present invention, it becomes possible to generate random numbers and a chip ID in various kinds of digital circuit.

In this regard, in the above-described embodiments, a description has been mainly given of a configuration of an integrated circuit. However, it is possible to mount the semiconductor integrated circuit described in the above embodiments, for example, on an information processing apparatus, such as a PC, etc., and to perform random-number generation or ID-generation processing, etc., in the information processing apparatus. The processing control may be performed in the control section in the LSI chip described in the above-described embodiments using a program stored in the memory in the LSI chip. Alternatively, it may be possible to employ a configuration, in which a program is performed using a control section or a memory formed in the other LSI element, etc., that is connected to an LSI chip in an information processing apparatus to input a command into an LSI chip having the above-described configuration in order to generate random numbers and an ID.

The present invention has been explained in detail by referring to the specific embodiments. However, it is obvious that those skilled in the art can perform modifications and substitutions on the embodiments without departing from the spirit of the present invention. That is to say, the present invention has been disclosed in a form of an example, and should not be limitedly interpreted. In order to determine the gist of the present invention, the appended claims should be taken into account.

Also, the series of processing described in the specification can be executed by hardware or by software or by the combination of both of these. When the processing is executed by software, the programs recording the processing sequence may be installed in a memory of a computer built in a dedicated hardware. Alternatively, the various programs may be installed and executed in a general-purpose computer capable of executing various processing. For example, the programs may be recorded in a recording medium in advance. In addition to installation from a recording medium to a computer, the programs may be received through a network, such as a LAN (Local Area Network) and the Internet, and may be installed in a recording medium, such as an internal hard disk, etc.

In this regard, the various processing described in this specification may be executed not only in time series in accordance with the description, but also may be executed in parallel or individually in accordance with the processing ability of the apparatus executing the processing or as necessary. Also, a system in this specification is a logical set of a plurality of apparatuses, and is not limited to a set of constituent apparatuses that are contained in a same case.

The present application contains subject matter related to that disclosed in Japanese Priority Patent Application JP 2009-120411 filed in the Japan Patent Office on May 18, 2009, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor integrated circuit comprising:
a plurality of flip-flops connected to a scan chain set as a test path of an integrated circuit; and
a data-collection section inputting setting values of the plurality of flip-flops connected to the scan chain through the scan chain or an independent connection path,
wherein the data-collection section inputs the setting values of the flip-flops at the time the power has been turned on to the plurality of flip-flops, and performs generation processing of random numbers, or random-number generation data, or fixed data on the basis of the input values.

2. The semiconductor integrated circuit according to claim 1, further comprising a control section performing control of changing a scan-test mode for performing scan test through the scan chain and a data collection mode for performing data collection through the scan chain,
wherein the data-collection section inputs the setting values of the flip-flops in accordance with a change to the data collection mode in the control section.

3. The semiconductor integrated circuit according to claim 2,
wherein the control section has a configuration capable of supplying power to the plurality of flip-flops connected to the scan chain in advance, and turning-on-power processing to the plurality of flip-flops is performed under the control of the control section.

4. The semiconductor integrated circuit according to claim 1,
wherein the data-collection section generates the fixed data by selecting a setting value corresponding to a specific flip-flop from the setting values of the plurality of flip-flops at the time of turning on the power.

5. The semiconductor integrated circuit according to claim 4,
wherein the data-collection section generates or holds flip-flop determination data discriminating a fixed-value-setting flip-flop holding a fixed setting value at power-on time and an uncertain-value-setting flip-flop at power-on time, and
the data-collection section selectively obtains only a setting value of a fixed-value-setting flip-flop from the setting values of the plurality of flip-flops at power-on time by applying the flip-flop determination data, and generates the fixed data from the obtained data.

6. The semiconductor integrated circuit according to claim 4 or claim 5,
wherein the data-collection section generates the fixed data as identification information (ID) corresponding to the semiconductor integrated circuit.

7. The semiconductor integrated circuit according to any one of claims 1 to 6,
wherein the data-collection section performs processing supplying a value generated by inputting the flip-flop setting values to data processing section included in the semiconductor integrated circuit.

8. An information processing apparatus including the semiconductor integrated circuit according to any one of claims 1 to 7.

9. A method of processing information in an information processing apparatus, the method comprising the steps of:
a data-collection section inputting setting values at power-on time of a plurality of flip-flops connected to a scan chain set as a test path of an integrated circuit through the scan chain or an independent connection path; and
the data-collection section performing generation processing of random numbers, or random-number generation data, or fixed data on the basis of the input values including setting values of the flip-flops at the time the power has been turned on to the plurality of flip-flops.

10. A program for performing information processing in an information processing apparatus, the program comprising the steps of:
a data-collection section inputting setting values at power-on time of a plurality of flip-flops connected to a scan chain set as a test path of an integrated circuit through the scan chain or an independent connection path; and
the data-collection section performing generation processing of random numbers, or random-number generation data, or fixed data on the basis of the input values including setting values of the flip-flops at the time the power has been turned on to the plurality of flip-flops.
